(19) United States
(12) Patent Application Publication
(10) Pub. No.: US 2001/0012688 A1
(43) Pub. Date: Aug. 9, 2001

(54) PROCESS FOR FORMING MINIATURE CONTACT HOLES IN SEMICONDUCTOR DEVICE WITHOUT SHORT-CIRCUIT

(76) Inventors: MASAKI KAWAGUCHI, TOKYO (JP); TAKEO FUJII, TOKYO (JP)

Correspondence Address: SUGHRUE MION ZINN MACPEAK & SEAS, 2100 PENNSYLVANIA AVENUE, WASHINGTON, DC, 20037

(21) Appl. No.: 09/160,100

(22) Filed: Sep. 25, 1998

(30) Foreign Application Priority Data
Sep. 29, 1997 (JP) 263515/97

(51) Int. Cl. H01L 21/4763

(52) U.S. Cl. 438/637; 438/639; 438/638

(57) ABSTRACT

In order to form a node contact hole in an inter-level insulating structure between bit lines spaced by the minimum length defined in design rules, a preliminary node contact hole is firstly formed in the inter-level insulating structure between the bit lines in such a manner as to have a length greater than the minimum length, and an insulating side wall spacer is formed on the inner surface defining the preliminary node contact hole so as to form the node contact hole having a length less than the minimum length, thereby forming a quite narrow node contact hole without a short-circuit between the bit lines and a storage node electrode.

### FIELD OF THE INVENTION

This invention relates to a process of fabricating a semiconductor device and, more particularly, to a process for forming miniature contact holes in a semiconductor device.

### DESCRIPTION OF THE RELATED ART

Semiconductor device manufacturers have increased circuit components of an integrated circuit fabricated on a single semiconductor chip. The circuit components have been scaled down for increasing the integration density, and contact holes are, accordingly, miniaturized.

FIG. 1 illustrates a typical example of the contact hole formed in the prior art semiconductor integrated circuit device. Impurity regions 1a, 1b and 1c are formed in a silicon substrate 2, and the impurity region 1a is shared between two field effect transistors. The two field effect transistors are spaced apart from each other, and have respective gate electrodes 3a/3b formed on gate oxide layers 3b/4b. The two field effect transistors and the impurity regions 1a/1b/1c are covered with an inter-level insulating layer 5.

When the prior art semiconductor integrated circuit device requires a contact hole for the impurity region 1, the contact hole is formed in the inter-level insulating layer 5 as follows. Photo-resist solution is spread over the upper surface of the inter-level insulating layer 5, and is baked so as to form a photo-resist layer on the inter-level insulating layer 5. An aligner (not shown) transfers a contact pattern image from a photo mask (not shown) to the photo-resist layer so as to form a latent image in the photo-resist layer, and the latent image is developed in developing solution. Then, the photo-resist layer is partially removed, and a photo-resist etching mask 6 is formed on the inter-level insulating layer 5. The photo-resist etching mask 6 exposes a part of the inter-level insulating layer 5 to etchant, and the inter-level insulating layer 5 is partially etched away. The manufacturer stops the etching at the major surface of the silicon substrate 2, and a contact hole 5a is formed in the inter-level insulating layer 5. Finally, the photo-resist etching mask 6 is stripped off.

Though not shown in FIG. 1, the contact hole 5a is plugged with a piece of conductive material, and a wiring strip on the inter-level insulating layer 5 is electrically connected through the piece of conductive material to the impurity region 1a. An electric signal is propagated from the wiring strip through the piece of conductive material to the impurity region 1a, and a control signal on the gate electrode 3a/3b controls the signal transfer from the impurity region 1a to the impurity region 1b/1c. It is necessary to perfectly isolate the gate electrodes 3a/3b from the piece of conductive material. If the contact hole 5a is either rightwardly or leftwardly moved from the target area, the gate electrode 3b/3a penetrates into the contact hole 5a, and is short-circuited with the piece of conductive material. As described hereinbefore, the aligner mechanically aligns the photo-mask with the target area on the photo-resist layer, and misalignment is unavoidable. For this reason, an appropriate margin is required for the contact hole 5a.

FIG. 2 illustrates another example of the prior art semiconductor integrated circuit device. Impurity regions 11a/11b/11c are formed in a silicon substrate 12 at intervals, and gate electrodes 13a/14a are formed on gate oxide layers 13b/14b over areas between the impurity regions 11a/11b/11c. The impurity regions 11a/11b/11c, the gate oxide layers 13b/14b and the gate electrodes 13a/14a form in combination field effect transistors.

The field effect transistors are covered with a lower inter-level insulating layer 15a, and wiring strips 16a/16b are formed on the lower inter-level insulating layer 15a. The wiring strips 16a/16b are covered with an upper inter-level insulating layer.

A contact hole 15c is formed in the upper/lower inter-level insulating layers 15a/15b as follows. Photo-resist solution is spread over the upper surface of the upper inter-level insulating layer 15b, and is baked so as to form a photo-resist layer on the inter-level insulating layer 15b. An aligner (not shown) transfers a contact pattern image from a photo mask (not shown) to the photo-resist layer so as to form a latent image in the photo-resist layer, and the latent image is developed in developing solution. Then, the photo-resist layer is partially removed, and a photo-resist etching mask 17 is formed on the inter-level insulating layer 15b. The photo-resist etching mask 17 exposes a part of the inter-level insulating layers 15a/15b to etchant, and the inter-level insulating layers 15a/15b are partially etched away. The manufacturer stops the etching at the major surface of the silicon substrate 12, and the contact hole 15c is formed in the inter-level insulating layers 15a/15b. Finally, the photo-resist etching mask 17 is stripped off.

Though not shown in FIG. 2, the contact hole 15c is plugged with a piece of conductive material, and an upper wiring strip is formed on the upper inter-level insulating layer 15b. The upper wiring strip is electrically connected through the piece of conductive material to the impurity region 11a. An electric signal is propagated from the upper wiring strip through the piece of conductive material to the impurity region 11a, and a control signal on the gate electrode 14a/14b controls the signal transfer from the impurity region 11a to the impurity region 11b/11c. The wiring strips 16a/16b propagate other electric signals, and the manufacturer needs to isolate the wiring strips 16a/16b from the piece of conductive material. Thus, it is necessary to perfectly isolate not only the gate electrodes 3a/3b but also the wiring strips 16a/16b from the piece of conductive material. If the contact hole 15c is either rightwardly or leftwardly moved from the target area, the wiring strip 16a/16b firstly penetrates into the contact hole 15c, because the contact hole 15c converges from the upper surface of the upper inter-level insulating layer 15b toward the major surface of the silicon substrate 12. Misalignment is unavoidable, and, for this reason, the contact hole 15c requires the margin larger than that of the contact hole 5a.

As described hereinbefore, the contact hole 5a/15c requires a margin due to the unavoidable misalignment between the photo-mask and the target area on the photo-resist layer. However, the miniaturization of circuit components are still required for the semiconductor integrated circuit, and severe design rules are used in a design work for the miniature circuit components. The severe design rules merely offer a small margin to the aligner, and the are liable to expose the gate electrode 3a/3b to the contact hole 5a. In fact, when the design rules defines the minimum dimensions to be 0.25 micron, the margin is negligible. The short-circuit between the gate electrode 3a/3b and the piece of conductive material reduces the production yield. This is the problem inherent in the prior art contact hole, and the problem is more serious in the prior art structure shown in FIG. 2 rather than the prior art structure shown in FIG. 1.

### SUMMARY OF THE INVENTION

It is therefore an important object of the present invention to provide a process for forming a contact hole in a semiconductor device which is free from short-circuit with conductive wiring strips patterned at the minimum dimension in an inter-level insulating structure.

To accomplish the object, the present invention proposes to have an insulating side wall spacer define a target hole in a preliminary hole formed by using a photo-lithography and an etching.

In accordance with one aspect of the present invention, there is provided a process for forming a hole comprising the steps of preparing a structure having a bottom layer, a first insulating layer covering the bottom layer and at least two conductive layers formed in the first insulating layer spaced apart from each other over the bottom layer by a distance measured in a direction, forming a preliminary hole in the first insulating layer reaching the bottom layer and having a first length greater than the distance in the direction, forming a second insulating layer conformably extending on an upper surface of the first insulating layer and an inner surface defining the preliminary hole and the bottom layer and etching the second insulating layer until the upper surface is exposed again so as to form a target hole having a second length less than the distance.

### BRIEF DESCRIPTION OF THE DRAWINGS

The features and advantages of the process will be more clearly understood from the following description taken in conjunction with the accompanying drawings in which:

FIG. 1 is a cross sectional view showing the structure of the contact hole formed in the prior art semiconductor integrated circuit device;

FIG. 2 is a cross sectional view showing the structure of the contact hole formed in another prior art semiconductor integrated circuit device;

FIG. 3 is a plane view showing the structure of a memory cell incorporated in a semiconductor dynamic random access memory device according to the present invention;

FIGS. 4A to 4E are cross sectional views taken along line A-A and showing a process for fabricating the memory cell;

FIGS. 5A to 5E are cross sectional views taken along line B-B and showing the process for fabricating the memory cell; and

FIGS. 6A to 6C are cross sectional views showing another process for fabricating a memory cell according to the present invention.

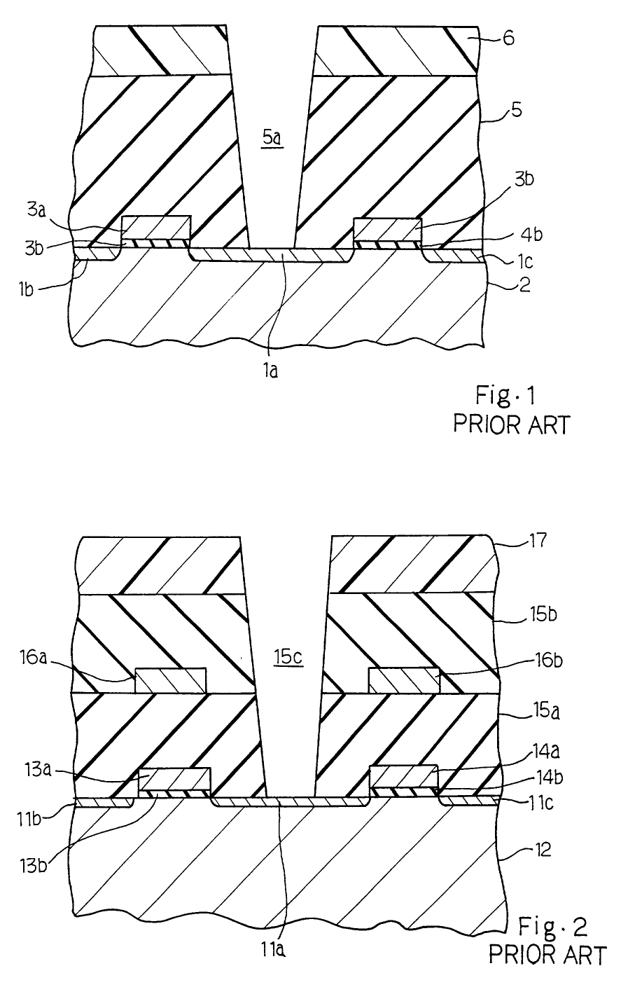

### DESCRIPTION OF THE PREFERRED EMBODIMENTS

First Embodiment

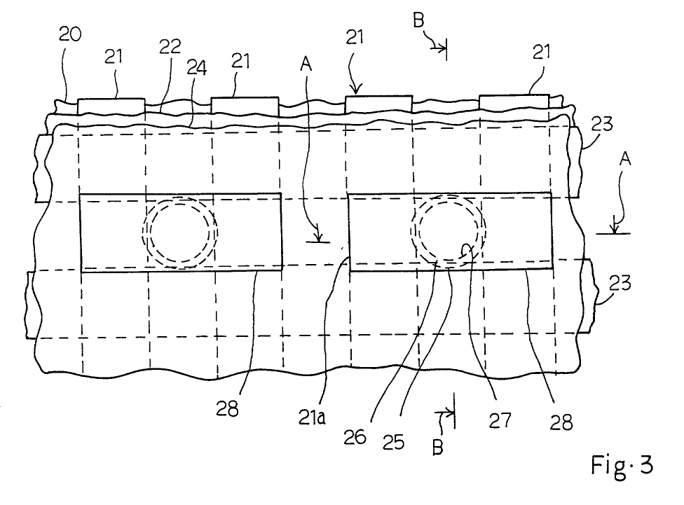

First, description is made on a dynamic random access memory cell with reference to FIG. 3. A passivation layer is removed from the semiconductor structure shown in FIG. 3, and inter-level insulating layers are partially cut away so as to make the layout clearly understood. The dynamic random access memory cell is fabricated on a silicon substrate 20, and a thick field oxide layer (not shown in FIG. 3) is selectively grown on the major surface of the silicon substrate 20. The thick field oxide layer defines plural active areas, and the dynamic random access memory cell is assigned to one of the plural active areas. Although only one dynamic random access memory cell is described, regions and layers of the other dynamic random access memory cells are labeled with the same references.

The dynamic random access memory cell is implemented by a series of an access transistor and a storage capacitor. Dopant impurity opposite in conductivity type to the silicon substrate 20 is selectively introduced into the active area, and forms a source region (not shown in FIG. 3) and a drain region (not shown in FIG. 3). A gate insulating layer (not shown in FIG. 3) is grown on the active area between the source region and the drain region, and a word line 21 extends over the gate insulating layer. Part of the word line 21 on the gate insulating layer serves as a gate electrode 21a of the access transistor. The word lines 21 are spaced apart from one another at intervals equal to the minimum space defined in design rules used for the semiconductor dynamic random access memory device.

The access transistor is covered with a lower inter-level insulating layer 22, and a bit line 23 extends on the lower inter-level insulating layer 22. Though not shown in FIG. 3, a bit contact hole is formed in the lower inter-level insulating layer 22 over the drain region, and the bit line 23 is electrically connected through the bit contact hole to the drain region. The bit lines 23 are spaced from one another at the intervals equal to the minimum space.

The bit line 23 is covered with an upper inter-level insulating layer 24, and a preliminary node contact hole 25 is formed in the lower inter-level insulating layer 22 and the upper inter-level insulating layer 24, and the source region is exposed to the preliminary node contact hole 25. The preliminary node contact hole 25 is wider than the gap between the word lines 21 and the gap between the bit lines 23. For this reason, the word lines 21 and the bit lines 23 are partially exposed to the preliminary node contact hole 25. An insulating side wall spacer 26 is formed on the inner walls of the inter-level insulating layers 22/24, and the word lines 21 and the bit lines 23 are perfectly covered with the insulating wide wall spacer 26.

The insulating side wall spacer 26 defines a node contact hole 27, and the node contact hole 27 has a diameter shorter than the minimum space. Although the preliminary node contact hole 25 and the node contact hole 27 have circular cross sections, respectively, a photo mask (not shown) for the preliminary node contact hole 25 has a square transparent area, and the square transparent area has the minimum dimensions defined in the design rules. However, the preliminary node contact hole 25 is circular in corss section, and is wider than the minimum dimensions. This phenomenon is derived from the following facts.

First, even through the photo mask for the preliminary node contact hole 25 has the square transparent area, the optical radiation forms a circular latent image in the photo-resist layer. The optical radiation is scattered at the corners of the square transparent area, and, accordingly, the photo-intensity is decreased around the corners. As a result, the latent image in the photo-resist layer is rounded, and a circular opening is formed in the photo-resist etching mask.

Second, the manufacturer intentionally increases the amount of exposure light so as to make the contact hole surely reach the impurity regions. A dispersion of light intensity is unavoidable in any stepper/aligner. Even if the manufacturer wants to make the light intensity constant over a shot area, the exposure energy is dispersed in the short area. When the manufacturer regulates the exposure energy to the limit to be required for pattern transfer of the minimum dimensions, there is a possibility that the exposure energy is too small to make the contact hole surely reach the impurity region. For this reason, the manufacture usually makes the exposure energy more than the limit. As a result, the latent image tends to be wider than the pattern image on the photo mask.

Third, the thickness of a photo-resist layer is varied from a central area of a silicon wafer toward the periphery. If a hundred semiconductor dynamic random access memory devices are fabricated on a silicon wafer, the node contact holes are equal to the product of 64 mega×100, and the manufacturer has to perfectly form the openings for such a large number of the node contact holes in the photo-resist layer. In this situation, the manufacturer slightly increases the exposure energy the limit to be required for the pattern transfer of the minimum dimensions, and the latent image becomes wider than the intervals of the word lines 21 and the intervals of the bit lines 23.

Fourth, misalignemnt in the stepper/aligner is unavoidable. Presently, the unavoidable misalignemnt is of the order of 0.05 micron. In other words, there is a possibility to offset the latent image for the preliminary node contact hole from the gap between the word lines 21 and the gap between the bit lines 23. This results in that the bit line 23 and/or the word line 21 is exposed to the preliminary node contact hole 25.

Finally, the amount of side etching is different between the word line/bit line 21/23 and the inter-level insulating layer 22/24 due to the difference in thickness. Although the side etching is presently precisely controllable, the difference in side etching is not ignoreable.

A storage node electrode 28 is formed on the upper inter-level insulating layer 24, and passes the node contact hole 27 so as to be held in contact with the source region. Although a cell plate electrode is opposed to the storage node electrode 28 through a dielectric layer, the cell plate electrode and the dielectric layer are omitted from the structure shown in FIG. 3.

As will be understood from the foregoing description, even though the word lines 21 and the bit lines 23 are patterned to have the gaps equal to the minimum space, the node contact holes 27 is narrower than the intervals of the word lines 21 and the intervals of the bit lines 23, and the memory cells are integrated on the silicon substrate 20 at high density. The insulating side wall spacer 26 prevents the storage node electrode 28 from the short-circuit with the word lines 21 and the bit lines 23, and the semiconductor dynamic random access memory device is operative without malfunction due to the short-circuit.

The dynamic random access memory cell shown in FIG. 3 are fabricated on the silicon substrate 20 as follows. The process starts with preparation of the silicon substrate 20. The field oxide layer 30 is selectively grown on the major surface of the silicon substrate 20, and defines the active areas 20a. The gate insulating layer 31 is grown on the active area 20a.

The word line 21 is formed, and extends on the thick field oxide layer 30 and the gate insulating layer 31. In this instance, the word line 21 has a polyside structure, i.e., a laminated structure of a doped polysilicon strip and a tungsten silicide strip. The doped polysilicon strip is 150 nanometers thick, and the tungsten silicide strip is 100 nanometers thick. The formation of the polyside structure is well known to a person skilled in the art, and no further description is incorporated hereinbelow for the sake of simplicity. The word lines 21 are patterned by using a photo-lithography and an etching. A photo-resist etching mask (not shown) for the word lines 21 has openings spaced at the minimum intervals defined in design rules.

The part of the word line 21 on the gate insulating layer 31 serves as the gate electrode 21a. Dopant impurity opposite in conductivity type to the silicon substrate 20 is, by way of example, ion implanted into the active area in a self-aligned manner with the gate electrode 21a, and forms the source region 20b and the drain region 20c in the active area 20a. The gate insulating layer 31, the gate electrode 21a, the source region 20b, the drain region 20c and a channel region between the source region 20b and the drain region 20c as a whole constitute the access transistor 32.

Insulating material is deposited over the entire surface of the resultant semiconductor structure, and forms the lower inter-level insulating layer 22. The access transistor 32 and the word lines 21 are covered with the lower inter-level insulating layer 22. The lower inter-level insulating layer 22 is chemically mechanically polished so as to create a flat surface.

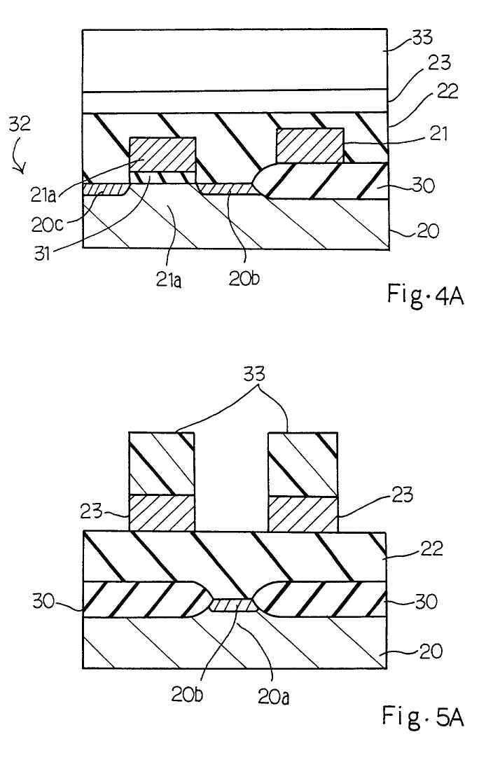

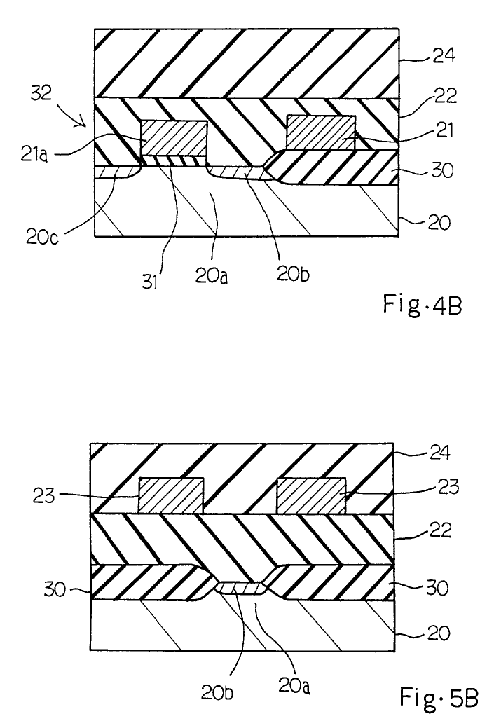

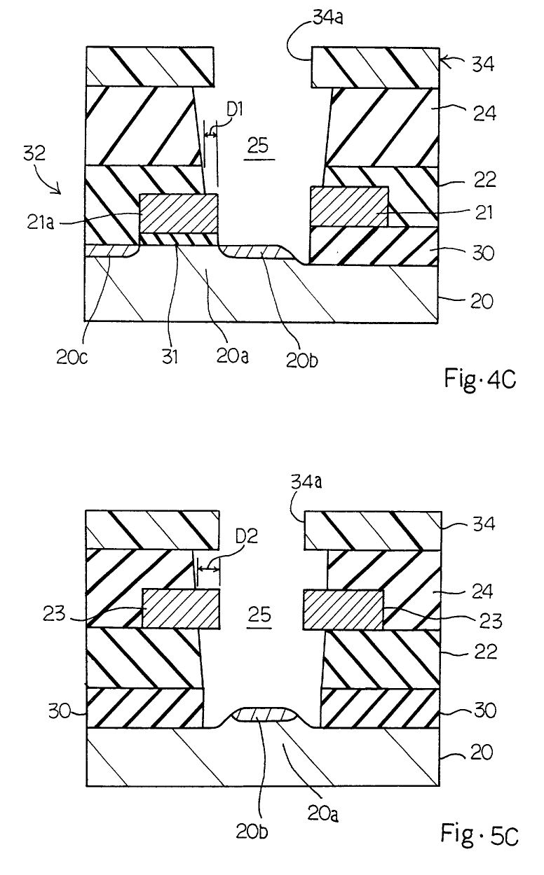

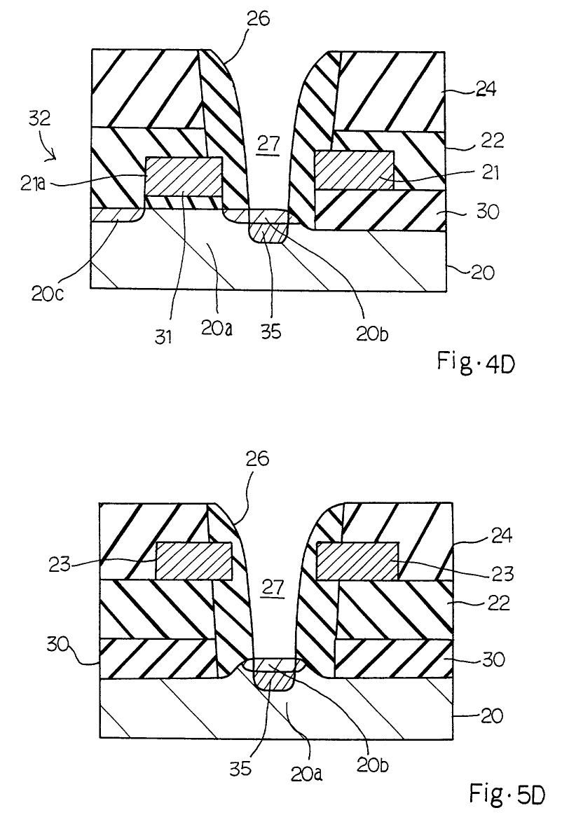

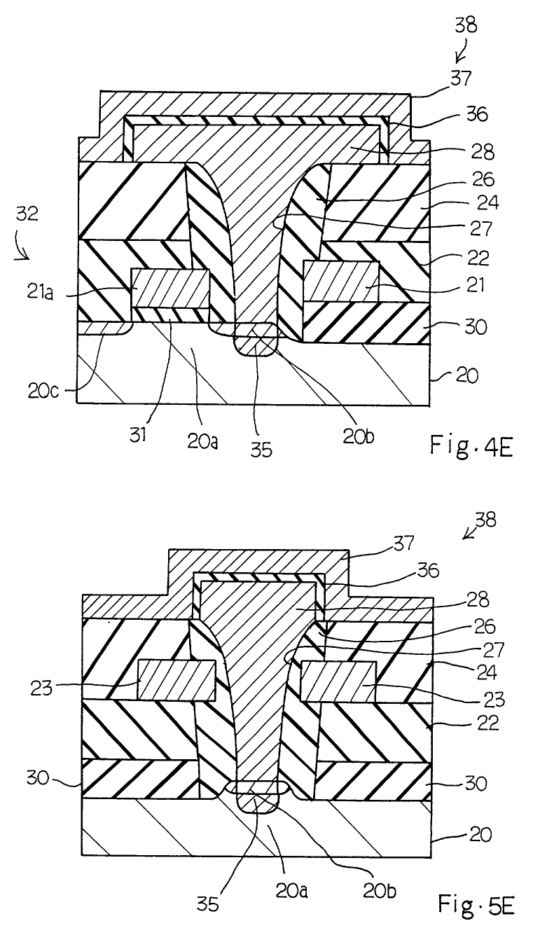

Conductive material such as tungsten silicide is deposited over the flat surface of the lower inter-level insulating layer 22. Photo-resist solution is spread over the entire surface of the tungsten suicide layer, and is baked so as to form a photo-resist layer (not shown). An aligner (not shown) transfers a pattern image for the bit lines 23 from a photo-mask (not shown) to the photo-resist layer so as to form a latent image. The latent image is developed in developing solution, and the photo-resist layer is formed into a photo-resist etching mask 33 (see FIGS. 4A and 5A). The photo-resist etching mask has openings spaced at intervals equal to the minimum space defined in the design rules. Using the photo-resist etching mask, the tungsten silicide layer is selectively etched away, and the bit lines 23 are formed on the lower inter-level insulating layer 22. The tungsten silicide layer is so thin that the side etching is ignoreable. For this reason, the bit lines 23 are spaced at the intervals equal to the minimum space. The bit lines may have the polyside structure.

The photo-resist etching mask 33 is stripped off, and insulating material is deposited over the entire surface of the resultant semiconductor structure. The insulating material forms the upper inter-level insulating layer 24, and the upper inter-level insulating layer 24 is chemically mechanically polished so as to create a flat surface as shown in FIGS. 4B and 5B.

Photo-resist solution is spread over the flat surface, and is baked so as to form a photo-resist layer. The aligner transfers a pattern image for a node contact hole from a photo-mask (not shown) to the photo-resist layer, and a latent image is formed in the photo-resist layer. The latent image is developed, and the photo-resist layer is formed into a photo-resist etching mask 34. Circular openings 34a are formed in the photo-resist etching mask 34 as described in conjunction with FIG. 3, and each circular opening 34 has a diameter greater than the minimum length defined in the design rules. Using the photo-resist etching mask 34, the upper inter-level insulating layer 24 and the lower inter-level insulating layer 22 are selectively etched away so as to form the preliminary node contact hole 25. The preliminary node contact hole 25 slightly converges toward the major surface of the silicon substrate 20, and the word lines 21 and the bit lines 23 are partially exposed to the preliminary contact hole 25 as shown in FIGS. 4C and 5C. The reasons for the wide preliminary node contact hole 25 are described hereinbefore. The word lines 21 and the bit lines 23 are assumed to project into the preliminary node contact hole 25 by D1 and D2, respectively.

The photo-resist etching mask 34 is stripped off, and insulating material is deposited over the entire surface of the resultant semiconductor structure by using a chemical vapor deposition, and the insulating material forms an insulating layer. The word lines 21 and the bit lines 23 are covered with the insulating layer, and the flat surface of the upper inter-level insulating layer 24 is also covered with the insulating layer. Using a reactive ion etching, the insulating layer is partially etched without any etching mask until the flat surface is exposed again. Then, the insulating side wall spacer 26 is left on the inner surfaces of the inter-level insulating layers 22/24, and defines the node contact hole 27 as shown in FIGS. 4D and 5D. While the reactive etching system is carrying out the anisotropic etching, the etching sidewardly proceeds, and the insulating side wall spacer 26 is made thinner than the insulating layer. If the amount of side etching is t1 at the word lines 21 and t2 at the bit lines 23, the insulating layer requires the thickness greater than (D1 and t1) at the word lines 21 and (D2+t2) at the bit lines 23. In other words, the chemical vapor deposition is continued until the insulating layer has the thickness greater than (D1 t+t1) at the word lines 21 and the thickness greater than (D2+t2) at the bit lines 23.

Subsequently, phosphorus is ion implanted into the source region 20b through the node contact hole 27 at dosage of 1×10¹⁵ atoms/cm² under acceleration energy of 30 KeV, and forms a heavily doped node contact region 35. The heavily doped node contact region 35 is nested in the source region 20b, and is deeper than the source region 20b.

Doped polysilicon is deposited over the entire surface of the resultant semiconductor structure by using a chemical vapor deposition. The doped polysilicon fills the node contact hole 27, and swells into a doped polysilicon layer. A photo-resist etching mask (not shown) is formed on the doped polysilicon layer, and the doped polysilicon layer is selectively etched away so as to form a storage node electrode 28. The insulating side wall spacer 26 isolates the word lines 21 and the bit lines 23 from the storage node electrode 28.

A composite dielectric layer 36 is formed on the storage node electrode 28, and consists of silicon oxide layers and a silicon nitride layer sandwiched between the silicon oxide layers. Polysilicon is deposited over the entire surface of the resultant semiconductor structure by using an atmospheric pressure chemical vapor deposition, and the cell plate electrode 37 is formed from the polysilicon layer as shown in FIGS. 4E and 5E. The storage node electrode 28, the composite dielectric layer 36 and the cell plate electrode 37 as a whole constitute a stacked storage capacitor 38, and the access transistor 32 and the stacked storage capacitor 38 form in combination the dynamic random access memory cell.

As will be appreciated from the foregoing description, even though the preliminary node contact hole 25 is expanded beyond the inner edges of the word lines 21 and the inner edges of the bit lines 23 patterned at intervals equal to the minimum space, the insulating side wall spacer 26 covers the exposed portions of the word lines 21 and the exposed portions of the bit lines 23, and any short-circuit never takes place between the word/bit lines 21/23 and the storage node electrode 28. The node contact hole 27 has the peripheral edges less than the minimum length defined by the design rules, and the memory cells are arranged on the silicon substrate 20 at high density.

In the first embodiment, the source region 20b serves as a bottom layer, and the lower inter-level insulating layer 22 and the upper inter-level insulating layer 24 as a whole constitute a first insulating layer. The word lines 21 or the bit lines 23 are corresponding to at least two conductive layers.

The minimum thickness of the insulating side wall spacer 26 is equal to the projections D1/D2, and the maximum thickness is less than a half of the difference between the diameter of the preliminary node contact hole 25 and the projection D1/D2.

Second Embodiment

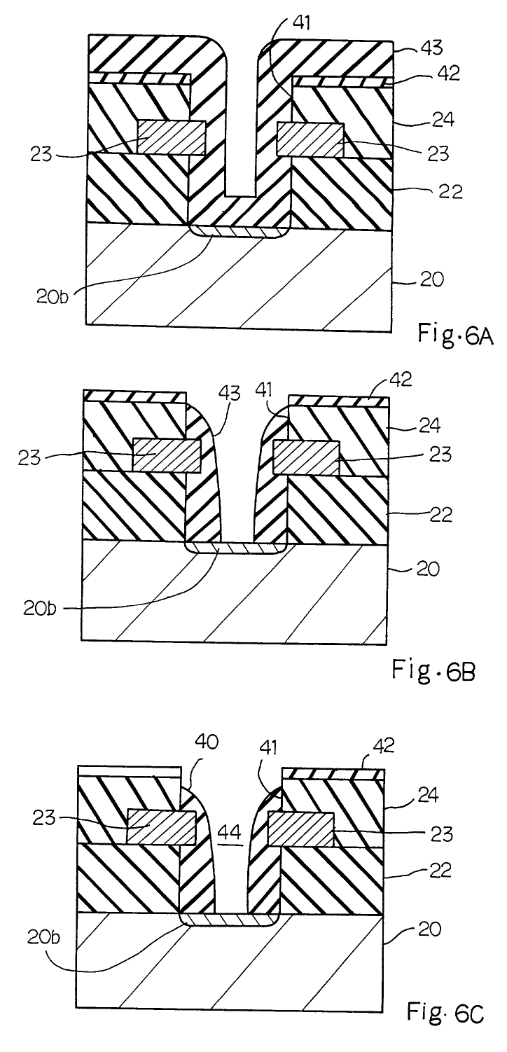

FIGS. 6A to 6C illustrate another process for fabricating a dynamic random access memory cell embodying the present invention. The process is similar to the process shown in FIGS. 4A to 4E and 5A to 5E except for formation of an insulating side wall spacer 40. For this reason, description is focused on the insulating side wall spacer 40. The other layers are labeled with the same references designating corresponding layers of the first embodiment without detailed description for avoiding repetition.

First, a preliminary contact hole 41 is formed in the inter-level insulating layers 22/24. The preliminary contact hole 41 is so wide that the bit lines 23 are exposed to the preliminary contact hole 41. An etching stopper layer 42 is formed on the upper inter-level insulating layer 24, and is formed of material offering a selectivity to an etchant in a reactive ion etching.

Insulating material is deposited over the entire surface of the resultant semiconductor structure, and forms an insulating layer 43 as shown in FIG. 6A. The insulating layer 43 is anisotropically etched by using the reactive ion etching. Even though the etching stopper 42 is exposed, the reactive ion etching is continued (see FIG. 6B). When the upper inter-level insulating layer 24 is exposed between the etching stopper 42 and the insulating side wall spacer 40, the manufacturer stops the reactive ion etching (see FIG. 6C).

The insulating side wall spacer 40 defines a contact hole 44 narrower than the gap between the bit lines 23, and achieves all the advantages of the first embodiment.

Although particular embodiments of the present invention have been shown and described, it will be apparent to those skilled in the art that various changes and modifications may be made without departing from the spirit and scope of the present invention. For example, the process according to the present invention is available for any contact hole narrower than the minimum dimensions defined by design rules. In other words, the present invention is never limited to the formation of the node contact hole.

What is claimed is:

1. A process for forming a hole, comprising the steps of:
a) preparing a structure having a bottom layer, a first insulating layer covering said bottom layer and at least two conductive layers formed in said first insulating layer spaced apart from each other over said bottom layer in by a distance measured in a direction;
b) forming a preliminary hole in said first insulating layer reaching said bottom layer and having a first length greater than said distance in said direction;
c) forming a second insulating layer conformably extending on an upper surface of said first insulating layer and an inner surface defining said preliminary hole and said bottom layer; and
d) etching said second insulating layer until said upper surface is exposed again so as to form a target hole having a second length less than said distance.

2. The process as set forth in claim 1, in which said step b) includes the sub-steps of
b-1) forming a photo-resist etching mask on said first insulating layer by using a photo-lithography, and
b-2) etching a part of said first insulating layer exposed to an opening of said photo-resist etching mask located over said bottom layer so that said at least two conductive layers are partially exposed to said preliminary hole.

3. The process as set forth in claim 2, in which said second insulating layer formed in said step c) has a thickness greater than the total of the length of said at least two conductive layers projecting from said inner surface and the distance between an inner surface of said second insulating layer before said step d) and a corresponding inner surface of said second insulating layer after said step d).

4. The process as set forth in claim 1, in which an anisotropic etching is used in said step d).

5. The process as set forth in claim 2, in which said first insulating layer has a first insulating sub-layer and a second insulating sub-layer laminated on said first insulating sub-layer, and said step a) includes the sub-steps of
a-1) forming a conductive layer on said second insulating sub-layer,
a-2) forming a photo-resist etching mask on said conductive layer by using said photo-lithography, and
a-3) selectively etching said conductive layer so as to form said at least two conductive layers from said conductive layer.

6. The process as set forth in claim 1, further comprising the step of forming an etching stopper on said upper surface of said first insulating layer between said step b) and said step c) so that said etching is carried out until said etching stopper is exposed in said step d).

7. The process as set forth in claim 1, in which said target hole serves as a node contact hole for a storage node electrode of a dynamic random access memory cell.

8. The process as set forth in claim 7, in which said at least two conductive layers serve as bit lines extending below said storage node electrode.

9. The process as set forth in claim 7, in which said at least two conductive layers serve as word lines extending below said storage node electrode.
